(19) United States
(12) Patent Application Publication
(10) Pub. No.: US 2026/0247991 A1
(43) Pub. Date: Aug. 20, 2026

(54) SEMICONDUCTOR DEVICE MANUFACTURING METHOD, STRUCTURE, AND SEMICONDUCTOR DEVICE

(71) Applicant: Resonac Corporation, Minato-ku, Tokyo (JP)

(72) Inventors: Motoo AOYAMA, Minato-ku, Tokyo (JP); Keiichi HATAKEYAMA, Minato-ku, Tokyo (JP); Kei ITAGAKI, Minato-ku, Tokyo (JP); Kazue HIRANO, Minato-ku, Tokyo (JP); Sadaaki KATO, Minato-ku, Tokyo (JP); Keiko UENO, Minato-ku, Tokyo (JP); Dongchul KANG, Minato-ku, Tokyo (JP); Hiroaki MATSUBARA, Minato-ku, Tokyo (JP)

(21) Appl. No.: 18/859,548

(22) PCT Filed: Aug. 30, 2023
(86) PCT No.: PCT/JP2023/031639

§ 371 Date: Oct. 24, 2024

(30) Foreign Application Priority Data
Sep. 5, 2022 (WO) PCT/JP2022/033315

(51) Int. Cl. H10W 70/05; H10W 70/60; H10W 72/00; H10W 74/01; H10W 74/10; H10W 74/15; H10W 90/00; H10W 90/10

(52) U.S. Cl. CPC H10W 70/096; H10W 70/611; H10W 72/0198; H10W 74/012; H10W 74/014; H10W 74/141; H10W 74/15; H10W 90/10; H10W 90/724

(57) ABSTRACT

In this method for producing a semiconductor device, first, a structure 200 including an interposer 60 in which a groove portion 61 for dividing a surface into a plurality of installation regions 65 is formed, and semiconductor elements 202a and 202b disposed on the respective installation regions 65 is prepared. The semiconductor element 202a is a processor, and the semiconductor element 202b is a memory. In the structure 200, the semiconductor elements 202a and 202b are sealed such that the sealing material 8 enters the groove portion 61. Then, the back surface of the interposer 60 is polished so that the sealing material 8 that has entered the groove portion 61 is exposed. Thereafter, the sealing material 8 is cut off along the groove portion 61 to be individualized, and a plurality of semiconductor devices 201 are acquired.

### TECHNICAL FIELD

The present disclosure relates to a method for producing a semiconductor device, a structure, and a semiconductor device.

### BACKGROUND ART

In response to the demand for higher functionality, various mounting methods for semiconductor elements have been developed. As an example, a 2.5D mounting is known in which a plurality of semiconductor elements are arranged close to each other on a silicon interposer, and the semiconductor elements are connected to each other via wiring formed in the silicon interposer (see, for example, Patent Literature 1).

A semiconductor device adopting such a mounting method using an interposer is manufactured through the following process. As an example, first, a plurality of semiconductor elements are disposed on an interposer, and each semiconductor element is connected to wiring formed in the interposer. Next, a sealing material is disposed on the interposer so as to cover the semiconductor element. Then, the sealing material and the interposer are cut off and individualized to obtain a plurality of semiconductor devices.

### CITATION LIST

### Patent Literature

Patent Literature 1: Japanese Unexamined Patent Publication No. 2018-037465

### SUMMARY OF INVENTION

### Technical Problem

In the process described above, for example, the interposer and the sealing material are sequentially cut off and individualized using a blade rotating at a high speed. Since the material of the interposer and the material of the sealing material are different from each other, it is necessary to cut off the interposer and the sealing material with different blades suitable for the respective materials. Therefore, for example, after the interposer is cut off using the blade for the interposer, the sealing material needs to be cut off after the blade is changed to the blade for the sealing material. The work of changing the blade at the time of such individualization becomes a cause of hindering improvement in production efficiency of the semiconductor device.

An object of the present disclosure is to provide a method for producing a semiconductor device, a structure, and a semiconductor device capable of improving production efficiency of the semiconductor device.

### Solution to Problem

[1] The present disclosure relates to, as one aspect, a method for producing a semiconductor device. This method for producing a semiconductor device includes: preparing a structure including an interposer including a first main surface and a second main surface opposed to the first main surface, the interposer including a groove portion formed to divide the first main surface into a plurality of regions, and a plurality of semiconductor elements, at least one of the semiconductor elements being arranged on each of the regions; sealing at least a part of each of the plurality of semiconductor elements with a sealing material such that the sealing material is disposed at least in the groove portion; polishing the interposer from the second main surface toward the first main surface such that the sealing material disposed in the groove portion is exposed; and individualizing the structure for each of the plurality of regions by cutting off the sealing material along the groove portion and acquiring a plurality of semiconductor devices.

In this producing method, a sealing material is disposed in the groove portion that divide the first main surface of the interposer into a plurality of regions, and the interposer is polished from the second main surface toward the first main surface such that the sealing material disposed in the groove portion is exposed. Then, the sealing material disposed in the groove portion is cut off to individualize (chip) the structure, and a plurality of semiconductor devices are acquired. In this case, the structure can be individualized by cutting off the sealing material disposed in the groove portion. Therefore, when the structure is individualized, for example, it is not necessary to use a blade for cutting off the interposer in addition to the blade for cutting off the sealing material. Thus, the production efficiency of the semiconductor device can be improved.
[2] In the method for producing the semiconductor device according to [1], the preparing the structure includes forming the groove portion having a depth of 10% to 60% with respect to a thickness of the interposer before being polished. When the depth of the groove portion to be formed is smaller than 10% of the thickness of the interposer before polishing, it is difficult to expose the sealing material in the polishing of the interposer. Further, in a case where the depth of the groove portion to be formed is larger than 60% of the thickness of the interposer before being polished, the strength of the interposer decreases, and there is a possibility that cracking occurs in the interposer in the producing process of the semiconductor device, and there is a possibility that the production efficiency decreases in order to prevent this cracking. On the other hand, according to the above producing method, the sealing material can be easily exposed in the step of polishing the interposer, and the interposer is hardly cracked in the producing process of the semiconductor device, so that the production efficiency is not reduced. Thus, the production efficiency of the semiconductor device can be improved.
[3] In the method for producing the semiconductor device according to [1] or [2], the preparing of the structure includes forming the groove portion having a depth of 70 μm to 470 μm. In a case where the depth of the groove portion to be formed is smaller than 70 μm, it is difficult to expose the sealing material in the step of polishing the interposer. Further, in a case where the depth of the groove portion to be formed is larger than 470 μm, the strength of the interposer decreases, and there is a possibility that cracking occurs in the interposer in the producing process of the semiconductor device, and there is a possibility that the production efficiency decreases in order to prevent this cracking. On the other hand, according to the above producing method, the sealing material can be easily exposed in the step of polishing the interposer, and the interposer is hardly cracked in the producing process of the semiconductor device, so that the production efficiency is not reduced. Thus, the production efficiency of the semiconductor device can be improved.
[4] In the method for producing the semiconductor device according to any one of [1] to [3], the interposer may be formed of silicon (Si). In this case, the wiring formed in the interposer can be miniaturized.
[5] In the method for producing the semiconductor device according to any one of [1] to [4], the preparing of the structure may include forming a re-distribution layer on the first main surface before the groove portion is formed, removing an overlapping portion of the re-distribution layer with a portion where the groove portion is to be formed, and forming the groove portion in the interposer. In this case, in the re-distribution layer, the overlapping portion with the portion where the groove portion is to be formed is removed. As a result, for example, when the groove portion is formed in the interposer using the blade, the blade is less likely to come into contact with the re-distribution layer. As a result, peeling and chipping (minute deficiency) of the re-distribution layer can be suppressed.
[6] In the method for producing a semiconductor device according to [5], the material forming the re-distribution layer may include a material having photosensitivity. In the step of removing the overlapping portion, the overlapping portion may be removed by performing exposure and development on the re-distribution layer. In this case, even if the overlapping portion in the re-distribution layer has a complicated shape or a fine shape, the overlapping portion can be easily removed.
[7] The method for producing the semiconductor device according to any one of [1] to [6] may further include disposing an underfill between the plurality of semiconductor elements and the first main surface before the sealing. In this case, for example, the semiconductor element is more stably fixed to the interposer by the underfill.
[8] In the method for producing a semiconductor device according to any one of [1] to [7], in the sealing, the sealing material may be disposed so as to cover a side surface and an upper surface of each of the semiconductor elements, and the method further may include polishing the sealing material such that the upper surface of each of the semiconductor elements is exposed from the sealing material. In this case, since the side surface of the semiconductor element is covered with the sealing material, the semiconductor element can be protected. Further, since the upper surface of the semiconductor element is exposed from the sealing material, heat dissipation of the semiconductor element can be improved. Note that, in this case, in the sealing, since the sealing material is also disposed in the groove portion of the interposer, the side surface of each portion of the individualized interposer is also covered with the sealing material. Accordingly, it is also possible to protect each portion of the interposer constituting the semiconductor device.
[9] In the method for producing the semiconductor device according to any one of [1] to [8], the preparing of the structure may include forming a groove portion by dicing the interposer using the first blade. In this case, the groove portion can be more reliably formed in the interposer by using the first blade.
[10] In the method for producing the semiconductor device according to any one of [1] to [9], in the acquiring of the plurality of semiconductor devices, the sealing material may be cut off along the groove portion using a second blade. In this case, the sealing material can be more reliably cut off.
[11] In the method for producing the semiconductor device according to [10], a grain size of an abrasive grain of the first blade may be larger than a grain size of an abrasive grain of the second blade. In this case, the interposer and the sealing material can be diced or cut off by the first blade and the second blade having abrasive grains suitable for the respective materials.
[12] In the method for producing the semiconductor device according to [11], the grain size of the abrasive grains of the first blade may be #2000 to #4000. The grain size of the abrasive grains of the second blade may be #320 to #600. In this case, the interposer and the sealing material can be diced or cut off by the first blade and the second blade having abrasive grains suitable for the respective materials.
[13] The present disclosure relates to a structure as another aspect. The structure includes an interposer including a first main surface and a second main surface opposed to the first main surface, and a plurality of semiconductor elements disposed on the first main surface. The interposer is formed with a groove portion that divides the first main surface into a plurality of regions. At least one of the plurality of semiconductor elements is disposed on each region. Note that, in the structure, two or more semiconductor elements may be disposed on each region.

In this structure, the interposer is formed with a groove portion that divides the first main surface into a plurality of regions. In a case where the semiconductor device is manufactured by the above-described producing method using this structure, the structure can be individualized by cutting off the sealing material disposed in the groove portion in the same manner as described above. Therefore, when the structure is individualized, for example, it is not necessary to use a blade for cutting off the interposer in addition to the blade for cutting off the sealing material. Thus, the production efficiency of the semiconductor device can be improved.
[14] In the structure according to [13], the groove portion may have a depth of 10% to 60% of a thickness of the interposer. In a case where the semiconductor device is manufactured by the above-described producing method using this structure, similarly to the above, the sealing material can be easily exposed in the step of polishing the interposer, and the interposer is hardly cracked in the producing process of the semiconductor device. Thus, the production efficiency of the semiconductor device can be improved.
[15] In the structure according to [13] or [14], the groove portion may have a depth of 70 μm to 470 μm. In a case where the semiconductor device is manufactured by the above-described producing method using this structure, similarly to the above, the sealing material can be easily exposed in the step of polishing the interposer, and the interposer is hardly cracked in the producing process of the semiconductor device. Thus, the production efficiency of the semiconductor device can be improved.
[16] In the structure according to any one of [13] to [15], the groove portion may be formed in a lattice shape including a plurality of first grooves along the first direction and a plurality of second grooves along the second direction intersecting the first direction. The interval between the first grooves adjacent to each other may be 10 mm to 100 mm. The interval between the second grooves adjacent to each other may be 20 mm to 100 mm. In a case where the semiconductor device is manufactured by the above-described producing method using this structure, the semiconductor device having a size that can be mounted on a general electronic component and having high versatility can be manufactured.
[17] The present disclosure relates to a semiconductor device as another aspect. The semiconductor device includes: an interposer; at least one semiconductor element disposed on a main surface of the interposer; and a sealing material configured to seal the interposer and the at least one semiconductor element. The sealing material covers at least a side surface of the interposer.

In this semiconductor device, the sealing material covers the side surface of the interposer. As a result, even in a case where the interposer is formed of a material (for example, silicon) having a relatively hard and brittle property, the interposer can be more reliably protected. As a result, a semiconductor device having high durability can be obtained.
[18] The semiconductor device according to [17] may further include a re-distribution layer that connects the interposer and the at least one semiconductor element. The sealing material may further cover the side surface of the re-distribution layer. As a result, the re-distribution layer can be protected by the sealing material, and a semiconductor device with higher durability can be obtained.

### Advantageous Effects of Invention

According to one aspect of the present disclosure, production efficiency of a semiconductor device can be improved.

### BRIEF DESCRIPTION OF DRAWINGS

FIG. 1 is a cross-sectional view schematically illustrating an example of a semiconductor device manufactured by a producing method according to a first embodiment.

FIG. 2 is a schematic cross-sectional view illustrating the method for producing the semiconductor device according to the first embodiment.

FIG. 3 is a schematic cross-sectional view illustrating the method for producing the semiconductor device according to the first embodiment.

FIG. 4 is a schematic cross-sectional view illustrating the method for producing the semiconductor device according to the first embodiment.

FIG. 5 is a plan view illustrating an interposer in which a groove portion is formed.

FIG. 6 is a schematic cross-sectional view illustrating the method for producing the semiconductor device according to the first embodiment.

FIG. 7 is a schematic cross-sectional view illustrating the method for producing the semiconductor device according to the first embodiment.

FIG. 8 is a diagram illustrating a configuration of an underfill.

FIG. 9 is a schematic cross-sectional view illustrating the method for producing the semiconductor device according to the first embodiment.

FIG. 10 is a schematic cross-sectional view illustrating the method for producing the semiconductor device according to the first embodiment.

FIG. 11 is a schematic cross-sectional view illustrating the method for producing the semiconductor device according to the first embodiment.

FIG. 12 is a schematic cross-sectional view illustrating the method for producing the semiconductor device according to the first embodiment.

FIG. 13 is a cross-sectional view schematically illustrating an example of a semiconductor device manufactured by a producing method according to a second embodiment.

FIGS. 14A to 14C are schematic cross-sectional views illustrating the method for producing the semiconductor device according to the second embodiment.

FIGS. 15A to 15C are schematic cross-sectional views illustrating the method for producing the semiconductor device according to the second embodiment.

FIGS. 16A to 16C are schematic cross-sectional views illustrating the method for producing the semiconductor device according to the second embodiment.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Further, unless otherwise specified, the positional relationship such as up, down, left, and right is based on the positional relationship illustrated in the drawings. Furthermore, the dimensional ratios in the drawings are not limited to the illustrated ratios.

In the present specification, the numerical range indicated using “to” includes the numerical values described before and after “to” as the minimum value and the maximum value, respectively. In the numerical ranges described in stages in the present specification, the upper limit value or the lower limit value described in one numerical range may be replaced with the upper limit value or the lower limit value of the numerical range described in another stage. Further, in the numerical range described in the present specification, the upper limit value or the lower limit value of the numerical range may be replaced with a value shown in examples.

### First Embodiment

### Configuration of Semiconductor Device

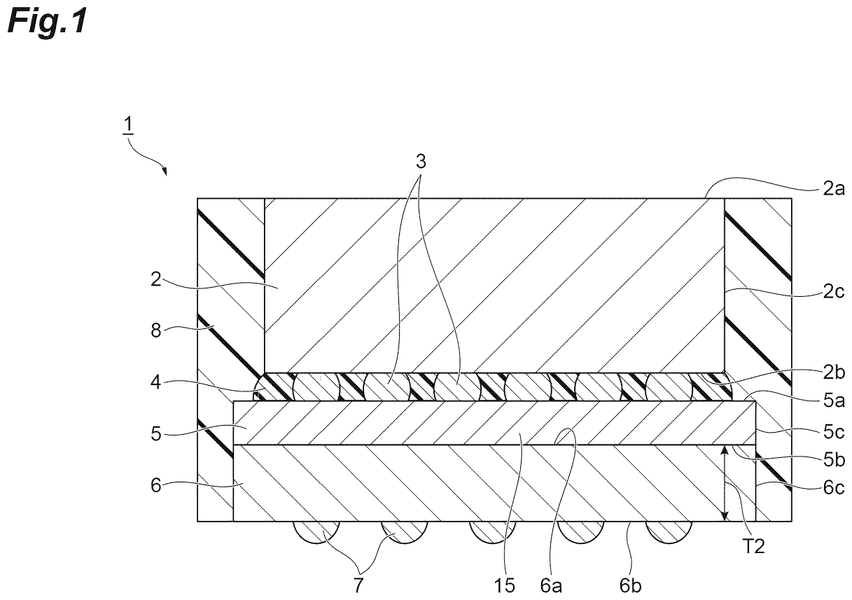

FIG. 1 is a cross-sectional view schematically illustrating an example of a semiconductor device 1 manufactured by a producing method according to the present embodiment. The semiconductor device 1 is, for example, a semiconductor package having a chip on wafer on substrate (CoWoS) structure. The semiconductor device 1 includes a semiconductor element 2, bumps 3, an underfill 4, a re-distribution layer 5, an interposer 6, bumps 7, and a sealing material 8. In CoWoS, the semiconductor device 1 having such a configuration is mounted on an organic substrate (not illustrated).

The semiconductor element 2 is, for example, a semiconductor chip such as a processor or a memory. The processor may be, for example, a processor unit such as a graphics processing unit (GPU) or a central processing unit (CPU). The memory may be, for example, a memory unit such as a high bandwidth memory (HBM). In the present embodiment, for convenience of explanation, a case where the semiconductor device 1 includes one semiconductor element 2 will be described as an example, but the semiconductor device 1 may include a plurality of semiconductor elements 2 (for example, refer to the second embodiment), and may include one processor unit and a plurality of memory units.

The semiconductor element 2 is disposed on the interposer 6 with the re-distribution layer 5 interposed therebetween. The semiconductor element 2 has an upper surface 2a, a lower surface 2b, and a side surface 2c connecting the upper surface 2a and the lower surface 2b. The upper surface 2a is located farther away from the interposer 6 than the lower surface 2b.

The bumps 3 are disposed between the semiconductor element 2 and the re-distribution layer 5 (RDL). The bumps 3 are disposed between the lower surface 2b of the semiconductor element 2 and a main surface 5a of the re-distribution layer 5 described later. The bumps 3 are formed of, for example, a metal material such as solder. The bumps 3 electrically connect the semiconductor element 2 and the re-distribution layer 5.

The underfill 4 is disposed between the semiconductor element 2 and the re-distribution layer 5 so as to cover the bumps 3. The underfill 4 is bonded to the semiconductor element 2 and the re-distribution layer 5. The underfill 4 seals and protects the bumps 3.

The re-distribution layer 5 is disposed between the bumps 3 and the interposer 6. The re-distribution layer 5 has main surfaces 5a and 5b that are opposite to each other, and a side surface 5c connecting the main surface 5a and the main surface 5b. The main surface 5a is located farther away from the interposer 6 than the main surface 5b. The bumps 3 and the underfill 4 are disposed on the main surface 5a. The re-distribution layer 5 is disposed directly on the interposer 6. The main surface 5b is in contact with the interposer 6. The re-distribution layer 5 includes a layered insulating portion 15 and wiring (not illustrated) formed in the insulating portion 15. The wiring electrically connects the bumps 3 and the interposer 6.

The interposer 6 is a substrate that supports the semiconductor element 2. In the present embodiment, the interposer 6 is formed in a rectangular plate shape. The shape of the interposer 6 is not limited, and the interposer 6 may be formed in a circular plate shape or a polygonal plate shape other than a rectangular shape. The interposer 6 includes main surfaces 6a and 6b that are opposite to each other, and a side surface 6c connecting the main surface 6a and the main surface 6b. The main surface 6a is in contact with the main surface 5b of the re-distribution layer 5. The interposer 6 is provided with wiring. The wiring may be a through electrode penetrating from the main surface 6a toward the main surface 6b. The wiring included in the interposer 6 electrically connects the wiring included in the re-distribution layer 5 and the bumps 7 to be described later. Note that, the side surface 6c of the interposer 6 is covered with the sealing material 8.

The bumps 7 are disposed on the main surface 6b of the interposer 6. The bumps 7 are formed of, for example, a metal material such as solder. The bumps 7 electrically connect the interposer 6 and another electronic component in a state where the semiconductor device 1 is mounted on the electronic component.

The sealing material 8 seals the semiconductor element 2 and the interposer 6. The sealing material 8 is annularly formed around the semiconductor element 2 when viewed from the thickness direction of the interposer 6. The sealing material 8 covers the side surface 2c of the semiconductor element 2, the surface of the underfill 4, the side surface 5c of the re-distribution layer 5, and the side surface 6c of the interposer 6. By being covered with the sealing material 8 in this manner, the durability of the semiconductor device 1 is enhanced. In particular, the interposer 6 may be formed of a material (for example, silicon) that is relatively hard and brittle. Even in this case, the interposer 6 can be more reliably protected by being covered with the sealing material 8. Further, the sealing material 8 does not cover the upper surface 2a of the semiconductor element 2 and the main surface 6b of the interposer 6. That is, the upper surface 2a and the main surface 6b are exposed from the sealing material 8. In the present embodiment, the entire upper surface 2a and the entire main surface 6b are exposed from the sealing material 8.

### Method for Producing Semiconductor Device

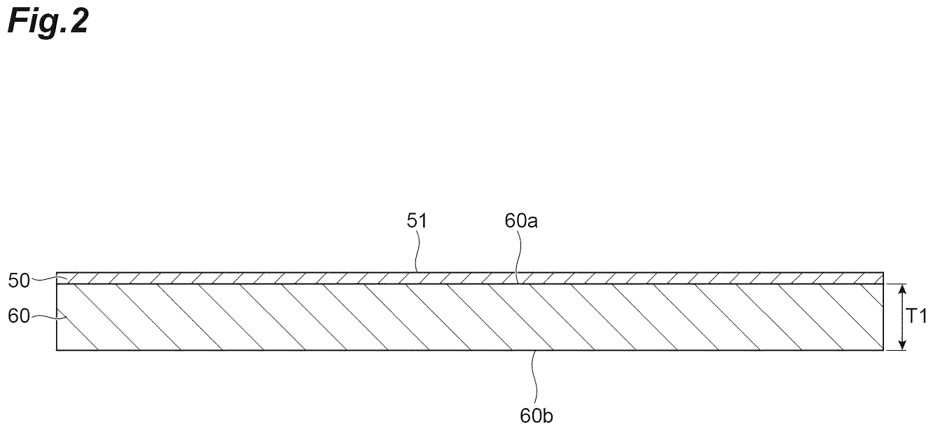

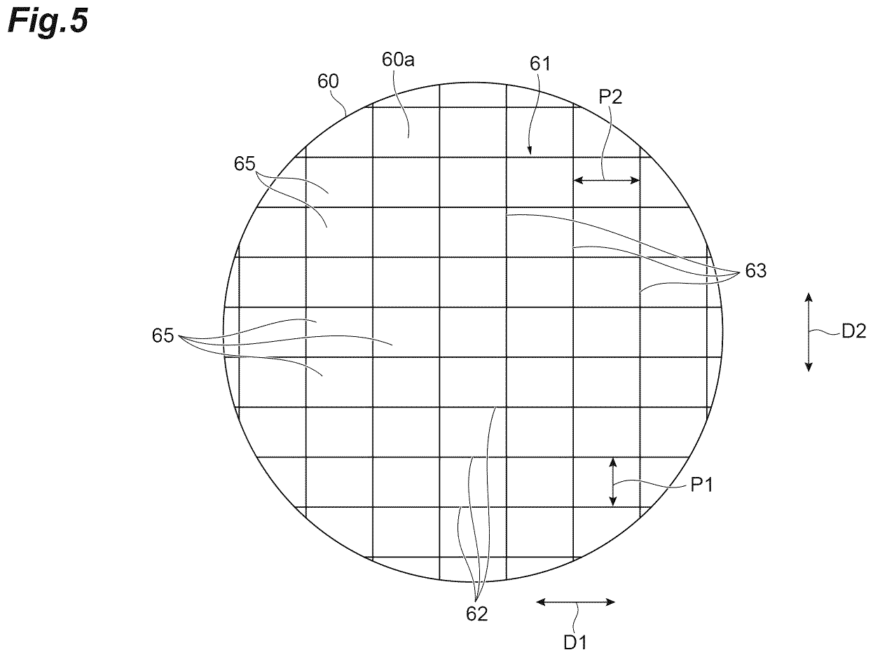

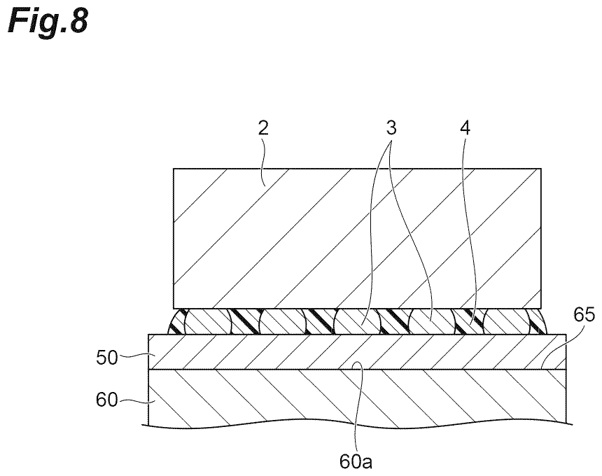

A method for producing the semiconductor device 1 will be described with reference to FIGS. 2 to 12. FIGS. 2 to 4, 6, 7, and 9 to 12 are schematic cross-sectional views illustrating the method for producing the semiconductor device 1. FIG. 5 is a plan view illustrating an interposer 60 in which a groove portion 61 is formed. FIG. 8 is a diagram illustrating a configuration of the underfill 4. The semiconductor device 1 is manufactured through, for example, the following steps (a) to (f).
(a) A step of preparing a structure 100 including: an interposer 60 including a main surface 60a (first main surface) and a main surface 60b (second main surface) opposite to the main surface 60a, and in which a groove portion 61 dividing the main surface 60a into a plurality of regions 65 are formed; and a plurality of semiconductor elements 2 disposed at least one by one on each region 65.
(b) A step of disposing the underfill 4 between the plurality of semiconductor elements 2 and the main surface 60a.
(c) A step of sealing at least a part of each of the plurality of semiconductor elements 2 with a sealing material 8 such that a sealing material 8 is disposed in at least the groove portion 61.
(d) A step of polishing the sealing material 8 such that the upper surface 2a of each semiconductor element 2 is exposed from the sealing material 8.
(e) A step of polishing the interposer 60 from the main surface 60b toward the main surface 60a so that the sealing material 8 disposed in the groove portion 61 is exposed.
(f) A step of individualizing the structure 100 for each of the plurality of regions 65 by cutting off the sealing material 8 along the groove portion 61 to acquire the plurality of semiconductor devices 1.

### Step (a)

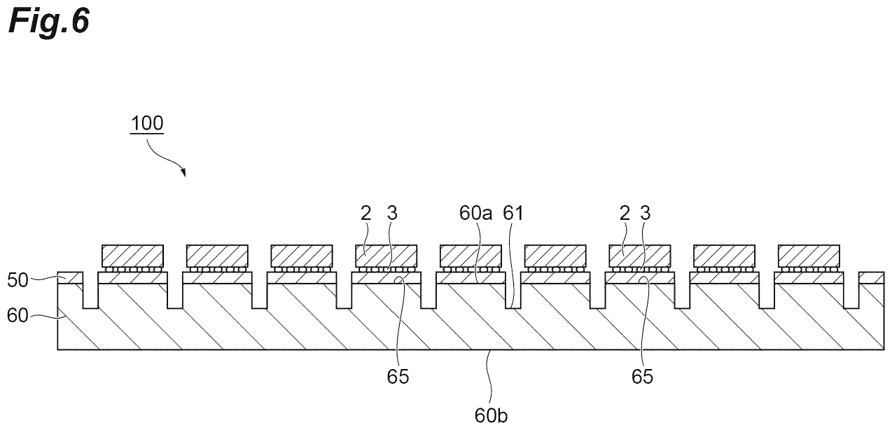

Step (a) will be described with reference to FIGS. 2 to 6. Step (a) is a step of preparing the structure 100 illustrated in FIG. 6. In step (a), first, as illustrated in FIG. 2, the interposer 60 is prepared. The interposer 60 is individualized in a later step to become the interposer 6 of the semiconductor device 1. The interposer 60 has a main surface 60a and a main surface 60b opposed to the main surface 60a. The direction in which the main surface 60a and the main surface 60b oppose each other is the thickness direction of the interposer 60. In the present embodiment, the interposer 60 is formed of silicon (Si). The interposer 60 has a circular plate shape. The interposer 60 may be formed of glass or an organic material, or may be an organic substrate formed using an organic material containing an inorganic filler. Such an organic substrate can be formed by, for example, laminating an interlayer insulating material (for example, an ABF film or the like) on a copper-clad laminate (for example, MCL series (product name, manufactured by Resonac Corporation)) that is a multilayer material as a core material. In a case where the interposer 60 is made of glass or an organic material, the interposer 60 may have a shape other than a circular plate shape (for example, a rectangular plate shape). The thickness T1 of the interposer 60 may be, for example, 500 μm to 1000 μm, or 700 μm to 800 μm. The interposer 60 is provided with wiring. The wiring may be a through-silicon via (TSV) penetrating from the main surface 60a toward the main surface 60b.

Next, a re-distribution layer 50 is formed on the main surface 60a of the interposer 60. The re-distribution layer 50 is individualized in a later step to become the re-distribution layer 5 of the semiconductor device 1. The re-distribution layer 50 is formed over the entire main surface 60a. The re-distribution layer 50 includes a layered insulating portion 51 and wiring (not illustrated) formed in the insulating portion 51. In the present embodiment, the insulating portion 51 is formed of an organic material. The organic material forming the insulating portion 51 may be a polyimide resin, a maleimide resin, an epoxy resin, a phenoxy resin, a polybenzoxal resin, an acrylic resin, or an acrylate resin. Note that, the insulating portion 51 of the re-distribution layer 50 may be formed using, for example, a photosensitive insulating material (for example, AH series (product name, manufactured by Resonac Corporation)).

The elastic modulus of the organic material is generally lower than the elastic modulus of the inorganic material. In other words, organic materials are generally softer than inorganic materials. The elastic modulus of the organic material forming the insulating portion 51 may be, for example, 1 GPa to 10 GPa. The elastic modulus here means Young's modulus.

The wiring included in the re-distribution layer 50 is formed of, for example, a metal material such as copper. The material forming the insulating portion 51 may have photosensitivity. In a case where the material for forming the insulating portion 51 has photosensitivity, a part of the insulating portion 51 may be removed by exposure and development, and a wiring may be formed on the removed portion by an electrolytic plating method or the like. Removal of the insulating portion 51 may be performed by laser irradiation. In the case of laser irradiation, the material forming the insulating portion 51 may not have photosensitivity. The wiring of the re-distribution layer 50 is electrically connected to the wiring of the interposer 60.

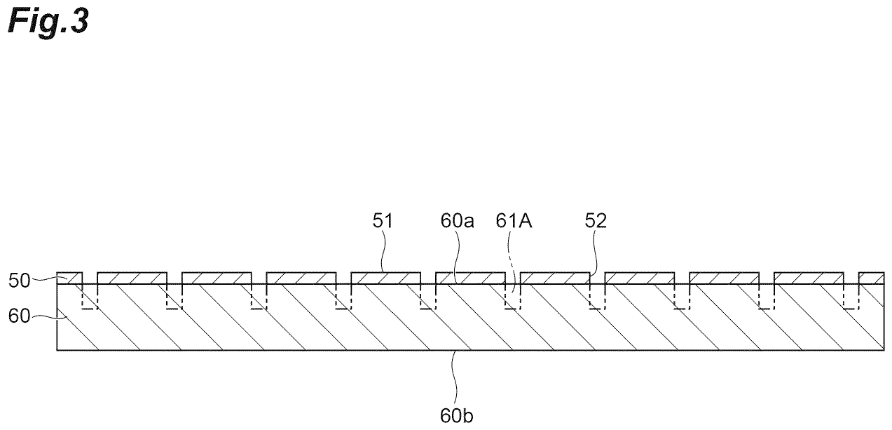

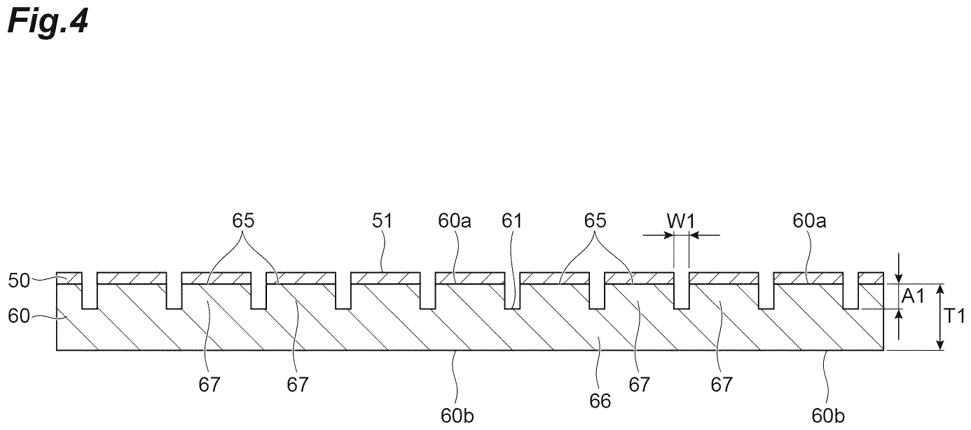

Next, as illustrated in FIG. 3, a part of the re-distribution layer 50 is removed. By removing a part of the re-distribution layer 50, an opening 52 is formed in the re-distribution layer 50. In the present embodiment, a groove portion 61 is formed in the interposer 60 after a part of the re-distribution layer 50 is removed (see FIG. 4). The detailed configuration of the groove portion 61 will be described later with reference to FIG. 4. In the step of removing a part of the re-distribution layer 50 illustrated in FIG. 3, a portion of the re-distribution layer 50 corresponding to the groove portion 61 is removed. Specifically, in FIG. 3, a portion of the interposer 60 where the groove portion 61 is to be formed is indicated by a two-dot chain line as a portion 61A. In the step of removing a part of the re-distribution layer 50 illustrated in FIG. 3, an overlapping portion of the re-distribution layer 50 with the portion 61A is removed. An overlapping portion with the portion 61A in the re-distribution layer 50 may be removed by performing exposure and development on the re-distribution layer 50, or may be removed by performing laser irradiation.

Next, as illustrated in FIG. 4, a groove portion 61 is formed in the interposer 60. The groove portion 61 is formed from the main surface 60a toward the main surface 60b of the interposer 60. The groove portion 61 is open on the main surface 60a. The groove portion 61 is formed in a slit shape. The depth A1 of the groove portion 61 may be, for example, 70 μm to 470 μm, 100 μm to 400 μm, or 200 μm to 300 μm. The depth A1 of the groove portion 61 with respect to the thickness T1 of the interposer 60 may be, for example, 10% to 60%, 20% to 50%, or 30% to 40%. The depth A1 of the groove portion 61 may be larger than the thickness T2 (see FIG. 1) of the interposer 6 of the semiconductor device 1 finally obtained by, for example, 30 μm to 50 μm. The aspect ratio (depth A1:width W1) of the width W1 of the groove portion 61 to the depth A1 of the groove portion 61 may be, for example, 3.5:1 to 8:1.

Here, a more detailed configuration of the groove portion 61 will be described with reference to FIG. 5. In FIG. 5, for convenience of explanation, illustration of the re-distribution layer 50 is omitted, and only the interposer 60 is illustrated. As illustrated in FIG. 5, the groove portion 61 includes a plurality of first grooves 62 along a first direction D1 and a plurality of second grooves 63 along a second direction D2 intersecting the first direction D1. That is, the groove portion 61 is formed in a lattice shape including the plurality of first grooves 62 and the plurality of second grooves 63. In the present embodiment, the second direction D2 is perpendicular to the first direction D1. An interval P1 between the first grooves 62 adjacent to each other may be, for example, 10 mm to 100 mm or 25 mm to 60 mm. An interval P2 between the second grooves 63 adjacent to each other may be, for example, 20 mm to 100 mm or 30 mm to 60 mm. The interval P2 may be larger than the interval P1.

The groove portion 61 divides the main surface 60a into a plurality of regions 65. In the present embodiment, each region 65 has a rectangular shape when viewed from the thickness direction of the interposer 60. The width of the region 65 along the first direction D1 is equal to the interval P2 between the second grooves 63 adjacent to each other. The width of the region 65 along the second direction D2 is equal to the interval P1 between the first grooves 62 adjacent to each other. The shape of each region 65 is not limited, and each region 65 may have, for example, a polygonal shape other than a rectangular shape. As illustrated in FIG. 4, the interposer 60 in which the groove portion 61 is formed includes a plate-shaped first portion 66 and a plurality of second portions 67 formed on the first portion 66. The second portion 67 has a mesa shape. The top surface of the second portion 67 corresponds to the region 65.

The groove portion 61 is formed using, for example, a blade (first blade). As an example, the groove portion 61 is formed by moving the blade rotating at a high speed from the main surface 60a toward the main surface 60b of the interposer 60 and dicing (machining) the interposer 60. The blade for dicing the interposer 60 may be, for example, a dicing blade. The grain size (count) of the abrasive grains of the blade for dicing the interposer 60 may be, for example, #2000 to #4000. The larger the # value indicating the grain size, the smaller the grain size of the abrasive grains. The abrasive grains may be diamond abrasive grains (SD). A method of forming the groove portion 61 is not limited, and the groove portion 61 may be formed by laser irradiation, for example.

Next, as illustrated in FIG. 6, the semiconductor element 2 is disposed on each region 65. In the present embodiment, one semiconductor element 2 is disposed on each region 65. At least one semiconductor element 2 may be disposed on each region 65. Therefore, a plurality of semiconductor elements 2 may be arranged on each region 65. As an example, one processor (for example, GPU) and a plurality of memories (for example, HBM) may be arranged on each region 65 as the plurality of semiconductor elements 2. In this case, in each region 65, the plurality of memories may be arranged close to the periphery of the processor. The processor and the memory may be arranged two-dimensionally without being stacked on each other. The plurality of memories may be stacked on each other and three-dimensionally arranged.

In the present embodiment, the re-distribution layer 50 is disposed on the interposer 60, and the semiconductor element 2 is disposed on the re-distribution layer 50 via the bumps 3. That is, the semiconductor element 2 is disposed on the region 65 via the re-distribution layer 50 and the bumps 3. The semiconductor element 2 is electrically connected to the wiring portion of the re-distribution layer 50 by the bumps 3. Through the above step (a), the structure 100 is prepared. The structure 100 to be prepared includes an interposer 60 and a plurality of semiconductor elements 2. The interposer 60 includes a main surface 60a and a main surface 60b opposed to the main surface 60a. The interposer 60 is formed with a groove portion 61 that divides the main surface 60a into a plurality of regions 65. At least one of the plurality of semiconductor elements 2 is disposed on each region 65. In the present embodiment, the plurality of semiconductor elements 2 are arranged one by one on each region 65.

### Step (b)

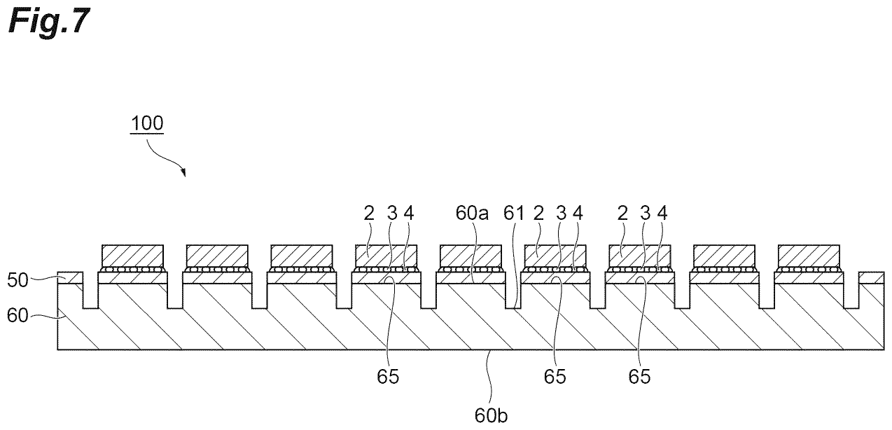

Step (b) is a step of disposing the underfill 4 between the plurality of semiconductor elements 2 and the main surface 60a of the interposer 60. As illustrated in FIG. 7, the underfill 4 is disposed between each semiconductor element 2 and the main surface 60a. In the present embodiment, the underfill 4 is disposed between the re-distribution layer 50 disposed on the main surface 60a and the semiconductor element 2. As illustrated in FIG. 8, the underfill 4 is disposed so as to cover the bumps 3 between the semiconductor element 2 and the re-distribution layer 5. The underfill 4 is filled in a gap between the bumps 3. The underfill 4 is bonded to the semiconductor element 2 and the re-distribution layer 50. The underfill 4 seals and protects the bumps 3. The underfill 4 may be formed of, for example, a material containing an epoxy resin. Note that, as the underfill 4, not only an individual underfill material may be used, but a part of the sealing material 8 may be used as an underfill at the time of sealing with the sealing material 8 described later.

### Step (c)

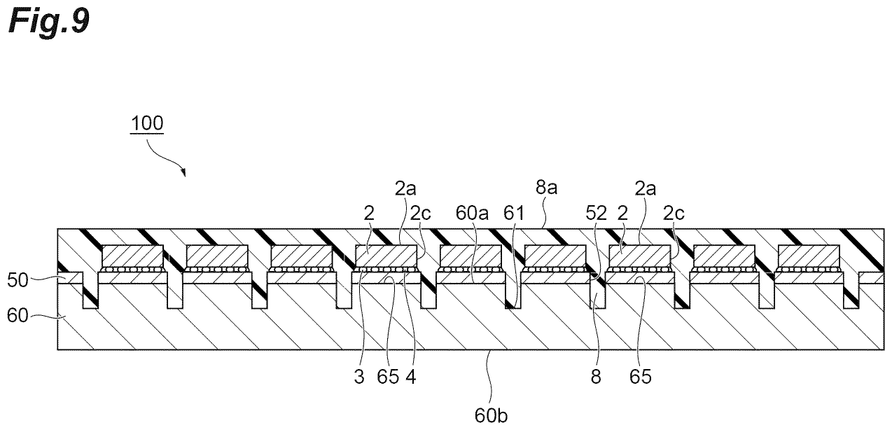

Step (c) is a step of disposing the sealing material 8 at least in the groove portion 61. As illustrated in FIG. 9, the plurality of semiconductor elements 2 are sealed with the sealing material 8 such that the sealing material 8 is disposed (filled) over the entire groove portion 61. The sealing material 8 is also disposed inside the opening 52 of the re-distribution layer 50 and between the plurality of semiconductor elements 2. The sealing material 8 is disposed over the entire interposer 60 so as to cover the semiconductor element 2, the underfill 4, and the re-distribution layer 50. The sealing material 8 is disposed so as to cover the upper surface 2a and the side surface 2c of each semiconductor element 2. The sealing material 8 may be formed of, for example, a material containing an epoxy resin. The sealing material 8 may be an epoxy molding compound (EMC).

### Step (d)

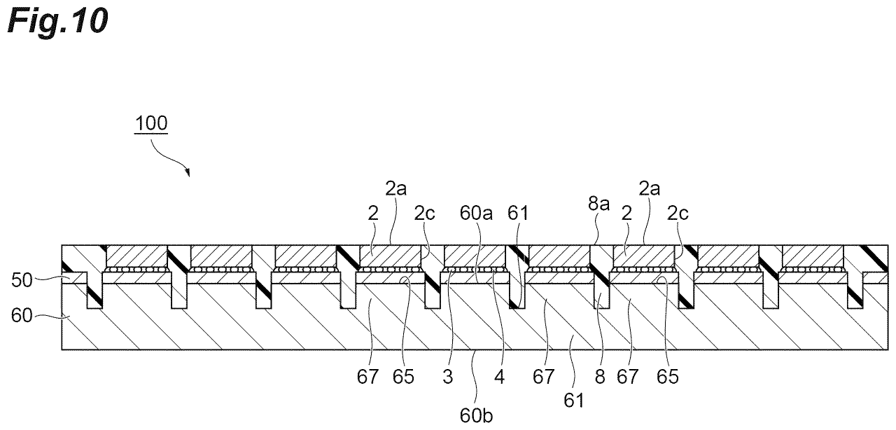

Step (d) is a step of polishing the sealing material 8 such that the upper surface 2a of each semiconductor element 2 is exposed from the sealing material 8. As illustrated in FIG. 9, the sealing material 8 has a surface 8a on a side opposite to the interposer 60. In step (d), the sealing material 8 is polished from the surface 8a toward the interposer 60, whereby the sealing material 8 is thinned. In the present embodiment, as illustrated in FIG. 10, the sealing material 8 is polished until the surface 8a is flush with the upper surface 2a. As a result, the upper surface 2a is exposed from the sealing material 8.

In the present embodiment, the direction of the interposer 60 is reversed after step (d) is completed. In the process up to step (d), the main surface 60a of the interposer 60 has been positioned above the main surface 60b in the vertical direction (see FIG. 10). On the other hand, in the process of step (e) and the subsequent steps, the interposer 60 is disposed such that the main surface 60a is positioned below the main surface 60b in the vertical direction.

### Step (e)

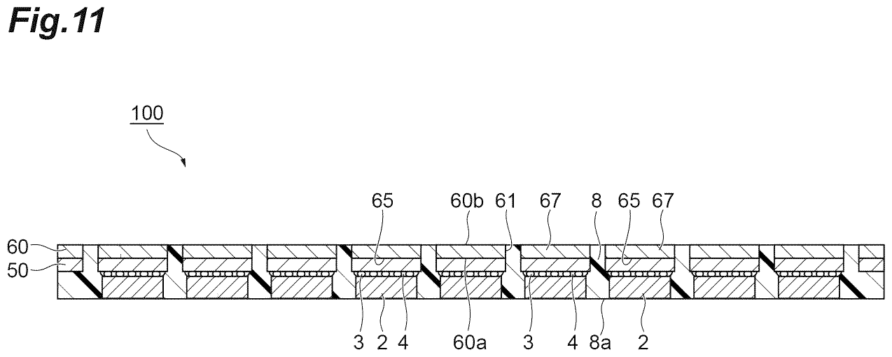

Step (e) is a step of polishing the interposer 60 so that the sealing material 8 disposed in the groove portion 61 is exposed. In step (e), the interposer 60 is polished from the main surface 60b toward the main surface 60a, whereby the interposer 60 is thinned. When the interposer 60 is polished until the sealing material 8 disposed in the groove portion 61 is exposed, the first portion 66 of the interposer 60 is removed and the plurality of second portions 67 remain as illustrated in FIG. 11. When viewed from the thickness direction of the interposer 60, only the sealing material 8 is present between the adjacent second portions 67.

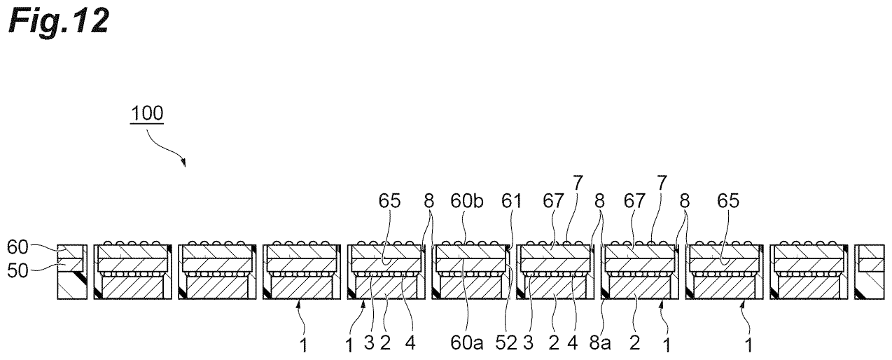

Next, as illustrated in FIG. 12, the bumps 7 are disposed on the interposer 60. In the present embodiment, the bumps 7 are disposed on the surface of each second portion 67 on a side opposite to the re-distribution layer 50. The bumps 7 are electrically connected to the wiring of the interposer 60.

### Step (f)

Step (f) is a step of individualizing the structure 100 for each of the plurality of regions 65 by cutting off the sealing material 8 along the groove portion 61 to acquire the plurality of semiconductor devices 1. As illustrated in FIG. 12, in step (f), the sealing material 8 is cut off in the thickness direction of the interposer 60. Specifically, a portion of the sealing material 8 disposed in the groove portion 61 (a portion disposed between the plurality of second portions 67), a portion of the sealing material 8 disposed in the opening 52 of the re-distribution layer 50, and a portion of the sealing material 8 disposed between the plurality of semiconductor elements 2 are cut off together. As a result, the structure 100 is individualized for each of the plurality of regions 65. As described above, when viewed from the thickness direction of the interposer 60, only the sealing material 8 exists between the adjacent second portions 67. Therefore, when the sealing material 8 is cut off in step (f), the interposer 60 is not cut off. In the present embodiment, the groove portion 61 is formed in a lattice shape when viewed from the thickness direction of the interposer 60. Therefore, the interposer 60 is cut off into a lattice shape along the groove portion 61.

The sealing material 8 is cut off using, for example, a blade (second blade). As an example, the sealing material 8 is cut off by a blade rotating at a high speed. The blade for cutting off the sealing material 8 may be, for example, a dicing blade. The grain size (count) of the abrasive grains of the blade for cutting off the sealing material 8 may be, for example, #320 to #600. The abrasive grains may be diamond abrasive grains (SD). The grain size of the abrasive grains of the blade (first blade) for dicing the interposer 60 in step (a) may be larger than the grain size of the abrasive grains of the blade (second blade) for cutting off the sealing material 8 in step (f).

The structure 100 is individualized by step (f), and a plurality of semiconductor devices 1 (see FIG. 1) are acquired. The individualized interposer 60 corresponds to the interposer 6 of the semiconductor device 1, and the individualized re-distribution layer 50 corresponds to the re-distribution layer 5 of the semiconductor device 1. Thus, the producing process of the semiconductor device 1 is completed.

As described above, according to the method for producing the semiconductor device 1 of the present embodiment, the sealing material 8 is disposed in the groove portion 61 that divides the main surface 60a of the interposer 60 into the plurality of regions 65, and the interposer 60 is polished from the main surface 60b toward the main surface 60a so that the sealing material 8 disposed in the groove portion 61 is exposed. Then, the sealing material 8 disposed in the groove portion 61 is cut off to individualize the structure 100, and a plurality of semiconductor devices 1 are acquired. In this case, the structure 100 can be individualized by cutting off the sealing material 8 disposed in the groove portion 61 without cutting off the interposer 60. Therefore, when the structure 100 is individualized, for example, it is not necessary to use a blade for cutting off the interposer 60 in addition to the blade for cutting off the sealing material 8. As a result, for example, it is not necessary to replace the blade, and the production efficiency of the semiconductor device 1 can be improved. Further, in the conventional producing method in which it is necessary to cut off both the interposer and the sealing material when the structure is individualized, the interposer may be cut off so that the blade reaches the sealing material in order to reliably cut off the interposer. In this case, the blade for cutting off the interposer contacts the sealing material. As described above, in a case where an object made of a material different from the original object is cut off, abnormal wear may occur in the blade. On the other hand, in the method for producing the semiconductor device 1 according to the present embodiment, when the structure 100 is individualized, it is not necessary to bring the blade for cutting off the sealing material 8 into contact with the interposer 60, so that abnormal wear hardly occurs in the blade. As a result, the life of the blade is extended and the frequency of replacement of the blade is reduced, so that the production efficiency of the semiconductor device 1 can be improved. Furthermore, in the semiconductor device 1 manufactured by the producing method according to the present embodiment, since the side surface 6c of the interposer 6 is covered with the sealing material 8, the interposer 6 can be protected. According to the above configuration in which the side surface 6c of the interposer 6 is covered with the sealing material 8, the interposer 6 can be more reliably protected even in a case where the interposer 6 is formed of silicon or the like having a relatively hard and brittle property.

In the method for producing the semiconductor device 1 of the present embodiment, the step of preparing the structure 100 may include a step of forming the groove portion 61 having the depth A1 of 10% to 60% with respect to the thickness T1 of the interposer 60. In a case where the depth A1 of the groove portion 61 is smaller than 10% of the thickness T1 of the interposer 60, it is difficult to expose the sealing material 8 in the step of polishing the interposer 60. Further, in a case where the depth A1 of the groove portion 61 is larger than 60% of the thickness T1 of the interposer 60, the strength of the interposer 60 decreases, and there is a possibility that cracking occurs in the interposer 60 in the producing process of the semiconductor device 1, and there is a possibility that the production efficiency decreases in order to prevent this cracking. On the other hand, according to the above producing method, the sealing material 8 can be easily exposed in the step of polishing the interposer 60, and the interposer 60 is hardly cracked in the producing process of the semiconductor device 1, so that the production efficiency is not reduced. Thus, the production efficiency of the semiconductor device 1 can be improved.

In the method for producing the semiconductor device 1 of the present embodiment, the step of preparing the structure 100 may include a step of forming the groove portion 61 having the depth A1 of 70 μm to 470 μm. In a case where the depth A1 of the groove portion 61 is smaller than 70 μm, it is difficult to expose the sealing material 8 in the step of polishing the interposer 60. Further, in a case where the depth A1 of the groove portion 61 is larger than 470 μm, the strength of the interposer 60 decreases, and there is a possibility that cracking occurs in the interposer 60 in the producing process of the semiconductor device 1, and there is a possibility that the production efficiency decreases in order to prevent this cracking. On the other hand, according to the above producing method, the sealing material 8 can be easily exposed in the step of polishing the interposer 60, and the interposer 60 is hardly cracked in the producing process of the semiconductor device 1, so that the production efficiency is not reduced. Thus, the production efficiency of the semiconductor device 1 can be improved.

In the method for producing the semiconductor device 1 of the present embodiment, the interposer 60 is formed of silicon (Si). In this case, the wiring formed in the interposer 60 can be miniaturized.

In the method for producing the semiconductor device 1 of the present embodiment, the step of preparing the structure 100 includes a step of forming the re-distribution layer 50 on the main surface 60a before the groove portion 61 is formed, a step of removing an overlapping portion of the re-distribution layer 50 with a portion (portion 61A) where the groove portion 61 is to be formed, and a step of forming the groove portion 61 in the interposer 60. In this case, in the re-distribution layer 50, the overlapping portion with the portion where the groove portion 61 is to be formed is removed. As a result, for example, when the groove portion 61 is formed in the interposer 60 using the blade, the blade is less likely to come into contact with the re-distribution layer 50. As a result, peeling and chipping (minute deficiency) of the re-distribution layer 50 can be suppressed.

In the method for producing the semiconductor device 1 of the present embodiment, the material forming the re-distribution layer 50 may include a material having photosensitivity. In the step of removing the overlapping portion, the overlapping portion may be removed by performing exposure and development on the re-distribution layer 50. In this case, even if the overlapping portion in the re-distribution layer 50 has a complicated shape or a fine shape, the overlapping portion can be easily removed.

The method for producing the semiconductor device 1 according to the present embodiment further includes a step of disposing the underfill 4 between the plurality of semiconductor elements 2 and the main surface 60a before the step of sealing the plurality of semiconductor elements 2 with the sealing material 8. In this case, the semiconductor element 2 is more stably fixed to the interposer 60 by the underfill 4.

In the method for producing the semiconductor device 1 according to the present embodiment, the step of sealing the plurality of semiconductor elements 2 with the sealing material 8 further includes a step of disposing the sealing material 8 so as to cover the side surface 2c and the upper surface 2a of each semiconductor element 2, and polishing the sealing material 8 so that the upper surface 2a of each semiconductor element 2 is exposed from the sealing material 8. In this case, since the side surface 2c of the semiconductor element 2 is covered with the sealing material 8, the semiconductor element 2 can be protected. Further, since the upper surface 2a of the semiconductor element 2 is exposed from the sealing material 8, heat dissipation of the semiconductor element 2 can be improved.

In the method for producing the semiconductor device 1 of the present embodiment, the step of preparing the structure 100 includes a step of forming the groove portion 61 by dicing the interposer 60 using the blade. In this case, the groove portion 61 can be more reliably formed with respect to the interposer 60 by using the blade.

In the method for producing the semiconductor device 1 of the present embodiment, in the step of acquiring the plurality of semiconductor devices 1, the sealing material 8 is cut off using a blade. In this case, the sealing material 8 can be more reliably cut off.

In the method for producing the semiconductor device 1 of the present embodiment, the grain size of the abrasive grains of the blade for dicing the interposer 60 in the step of forming the groove portion 61 may be larger than the grain size of the abrasive grains of the blade for cutting off the sealing material 8 in the step of acquiring the plurality of semiconductor devices 1. In this case, the interposer 60 and the sealing material 8 can be cut off or diced by a blade having abrasive grains suitable for the respective materials.

In the method for producing the semiconductor device 1 of the present embodiment, the grain size of the abrasive grains of the blade for dicing the interposer 60 in the step of forming the groove portion 61 may be #2000 to #4000. The grain size of the abrasive grains of the blade for cutting off the sealing material 8 in the step of acquiring the plurality of semiconductor devices 1 may be #320 to #600. In this case, the interposer 60 and the sealing material 8 can be cut off or diced by a blade having abrasive grains suitable for the respective materials.

In the structure 100 according to the present embodiment, the interposer 60 is formed with the groove portion 61 that divides the main surface 60a into the plurality of regions 65. In a case where the semiconductor device 1 is manufactured by the above-described producing method using the structure 100, the structure 100 can be individualized by cutting off the sealing material 8 disposed in the groove portion 61 without cutting off the interposer 60 in the same manner as described above. Therefore, when the structure 100 is individualized, for example, it is not necessary to use a blade for cutting off the interposer 60 in addition to the blade for cutting off the sealing material 8. Thus, the production efficiency of the semiconductor device 1 can be improved.

In the structure 100 of the present embodiment, the groove portion 61 may have a depth A1 of 10% to 60% with respect to the thickness T1 of the interposer 60. In a case where the semiconductor device 1 is manufactured by the above-described producing method using this structure 100, similarly to the above, the sealing material 8 can be easily exposed in the step of thinning the interposer 60, and the interposer 60 is hardly cracked in the producing process of the semiconductor device 1. Thus, the production efficiency of the semiconductor device 1 can be improved.

In the structure 100 of the present embodiment, the groove portion 61 may have a depth A1 of 70 μm to 470 μm. In a case where the semiconductor device 1 is manufactured by the above-described producing method using this structure 100, similarly to the above, the sealing material 8 can be easily exposed in the step of thinning the interposer 60, and the interposer 60 is hardly cracked in the producing process of the semiconductor device 1. Thus, the production efficiency of the semiconductor device 1 can be improved.

In the structure 100 of the present embodiment, the groove portion 61 is formed in a lattice shape including the plurality of first grooves 62 along the first direction D1 and the plurality of second grooves 63 along the second direction D2 perpendicular to the first direction. The interval between the first grooves 62 adjacent to each other may be 10 mm to 100 mm. The interval between the second grooves 63 adjacent to each other may be 20 mm to 100 mm. In a case where the semiconductor device 1 is manufactured by the above-described producing method using this structure 100, the semiconductor device 1 having a size that can be mounted on a general electronic component and having high versatility can be manufactured.

### Second Embodiment

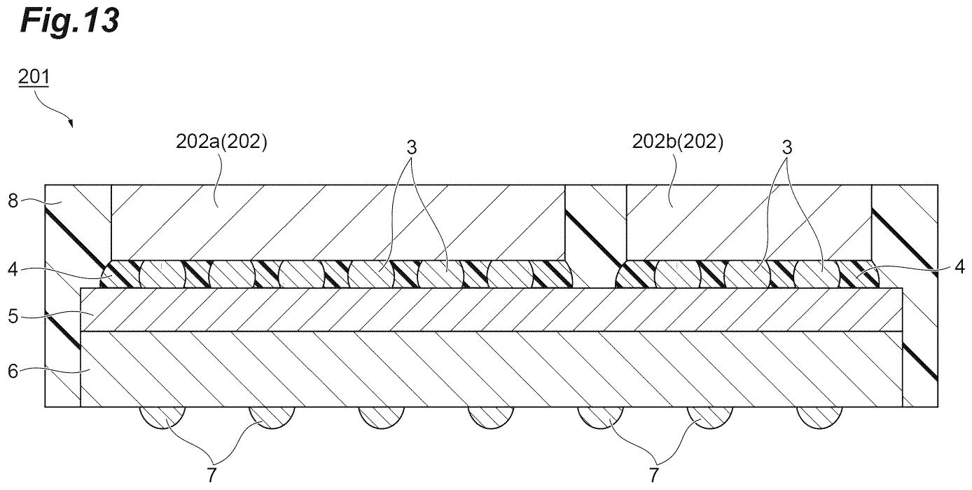

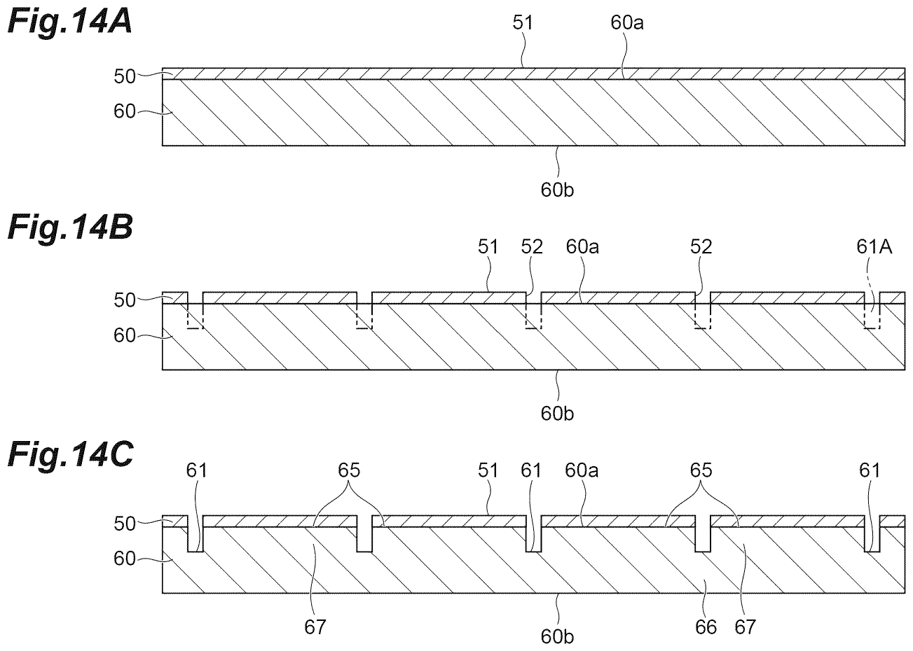

Next, a semiconductor device according to a second embodiment and a method for producing the same will be described with reference to FIGS. 13 to 16. FIG. 13 is a cross-sectional view schematically illustrating an example of a semiconductor device 201 manufactured by the producing method according to the second embodiment. FIGS. 14 to 16 are schematic cross-sectional views illustrating the method for producing the semiconductor device according to the second embodiment. The semiconductor device 201 according to the second embodiment is, for example, a semiconductor package having a chip on wafer on substrate (CoWoS) structure, and is different from the first embodiment in that a plurality of semiconductor elements are mounted on each semiconductor device. Since the other configurations are similar, the description thereof may be omitted below. As illustrated in FIG. 13, the semiconductor device 201 includes a plurality of semiconductor elements 202 (202a, 202b), bumps 3, underfills 4, a re-distribution layer 5, an interposer 6, bumps 7, and a sealing material 8.

The semiconductor element 202 is, for example, a semiconductor chip such as a processor or a memory. The processor may be, for example, a processor unit such as a graphics processing unit (GPU) or a central processing unit (CPU). The memory may be, for example, a memory unit such as a high bandwidth memory (HBM). In the example illustrated in FIG. 13, for example, one semiconductor element 202a is a processor unit, and the other semiconductor element 202b is a memory. The semiconductor element 202b may be a memory unit in which a plurality of memories are stacked. In the semiconductor device 201 according to the second embodiment, since the plurality of semiconductor elements 202 are provided, the sealing material 8 is configured to enter between the semiconductor elements 202. Further, the semiconductor elements 202a and 202b may be electrically connected to each other by the re-distribution layer 5 or a built-in chip or the like disposed in the re-distribution layer 5.

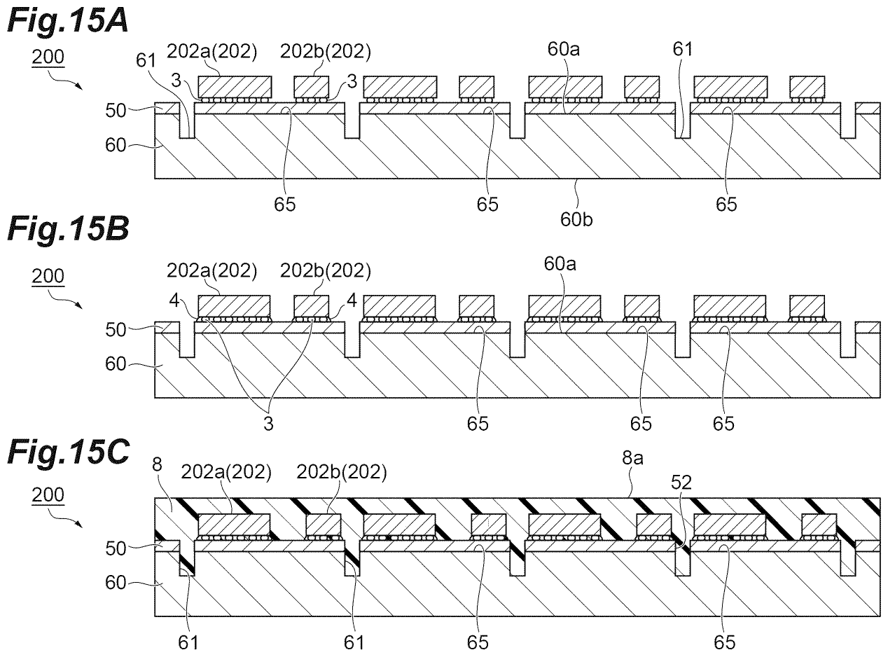

Next, a method for producing the semiconductor device 201 will be described with reference to FIGS. 14 to 16. Step (a) is a step of preparing a structure 200 illustrated in FIG. 15A. In step (a), first, as illustrated in FIG. 14A, the interposer 60 is prepared. The interposer 60 is individualized in a later step to become the interposer 6 of the semiconductor device 201. The re-distribution layer 50 is formed on the main surface 60a of the interposer 60. The re-distribution layer 50 is individualized in a later step to become the re-distribution layer 5 of the semiconductor device 201. The re-distribution layer 50 is formed over the entire main surface 60a. The re-distribution layer 50 includes a layered insulating portion 51 and wiring (not illustrated) formed in the insulating portion 51.

Next, as illustrated in FIG. 14B, a part of the re-distribution layer 50 is removed. By removing a part of the re-distribution layer 50, an opening 52 is formed in the re-distribution layer 50. In the present embodiment, a groove portion 61 is formed in the interposer 60 after a part of the re-distribution layer 50 is removed (see FIG. 14C). A method of removing a part of the re-distribution layer 50 is similar to that in the first embodiment.

Next, as illustrated in FIG. 14C, the groove portion 61 is formed in the interposer 60. The groove portion 61 is formed from the main surface 60a toward the main surface 60b of the interposer 60. The groove portion 61 is open on the main surface 60a. The groove portion 61 is formed in a slit shape. As in the first embodiment, the depth of the groove portion 61 may be, for example, 70 μm to 470 μm, 100 μm to 400 μm, or 200 μm to 300 μm. The depth of the groove portion 61 with respect to the thickness of the interposer 60 may be, for example, 10% to 60%, 20% to 50%, or 30% to 40%. The depth of the groove portion 61 may be larger than the thickness of the interposer 6 of the semiconductor device 201 finally obtained by, for example, 30 μm to 50 μm. The aspect ratio (depth: width) of the width of the groove portion 61 to the depth of the groove portion 61 may be, for example, 3.5:1 to 8:1.

Further, as in the first embodiment, the groove portion 61 divides the main surface 60a into a plurality of regions 65. When viewed from the thickness direction of the interposer 60, each region 65 has a rectangular shape. In each region 65, a plurality of semiconductor elements are installed in a process to be described later. That is, each region 65 has a size in which a plurality of semiconductor elements (for example, semiconductor elements 202a and 202b) can be arranged. Such a groove portion 61 is formed using a blade, for example, as in the first embodiment.

Next, as illustrated in FIG. 15A, the plurality of semiconductor elements 202 are arranged on each region 65. In the second embodiment, two semiconductor elements 202 are arranged on each region 65. As an example, the semiconductor element 202a that is a processor (for example, GPU) and the semiconductor element 202b that is a memory (for example, HBM) are arranged on each region 65. In a case where a plurality of memories are installed, the memories may be stacked and three-dimensionally arranged.

Step (b) is a step of arranging the underfill 4 between each of the semiconductor elements 202a and 202b and the re-distribution layer 50 as illustrated in FIG. 15B.

### Step (c)

Step (c) is a step of disposing the sealing material 8 at least in the groove portion 61. As illustrated in FIG. 15C, the plurality of semiconductor elements 202 are sealed with the sealing material 8 such that the sealing material 8 is disposed (filled) over the entire groove portion 61. The sealing material 8 is also disposed inside the opening 52 of the re-distribution layer 50 and between the plurality of semiconductor elements 202. The sealing material 8 is disposed over the entire interposer 60 so as to cover the semiconductor elements 202a and 202b, the underfill 4, and the re-distribution layer 50. The sealing material 8 is disposed so as to cover the upper surface and the side surface of each semiconductor elements 202a and 202b.

### Step (d)

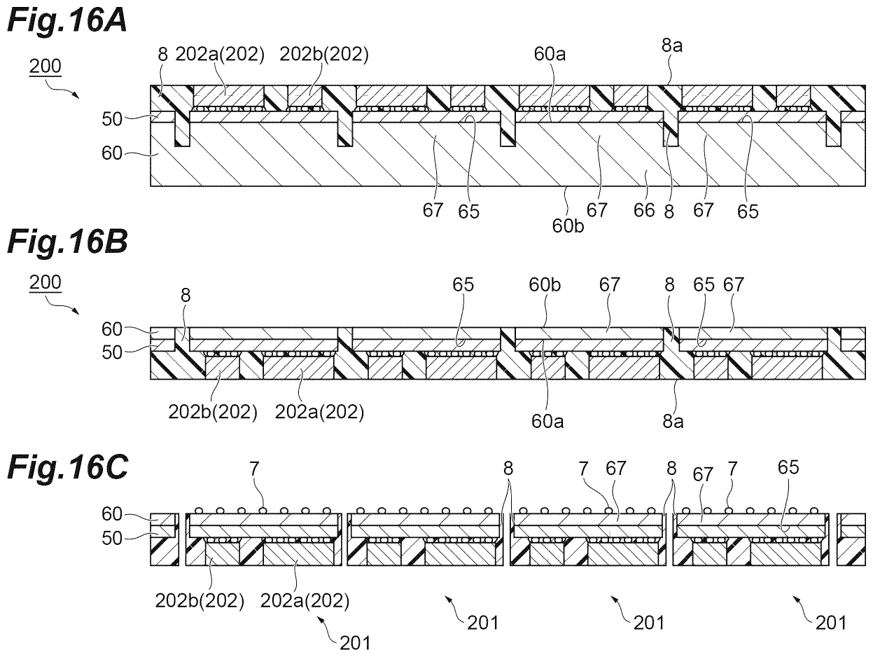

Step (d) is a step of polishing the sealing material 8 such that the upper surfaces of semiconductor elements 202a and 202b are exposed from the sealing material 8. As illustrated in FIG. 16A, the sealing material 8 has a surface 8a on a side opposite to the interposer 60. In step (d), the sealing material 8 is polished from the surface 8a toward the interposer 60, whereby the sealing material 8 is thinned. In the present embodiment, as illustrated in FIG. 16A, the sealing material 8 is polished until the surface 8a is flush with the upper surfaces of the semiconductor elements 202a and 202b. As a result, the upper surfaces of the semiconductor elements 202a and 202b are exposed from the sealing material 8.

In the present embodiment, the direction of the interposer 60 is reversed after step (d) is completed as in the first embodiment. In the process up to step (d), the main surface 60a of the interposer 60 has been positioned above the main surface 60b in the vertical direction (see FIG. 16A). On the other hand, in the process of step (e) and the subsequent steps, the interposer 60 is disposed such that the main surface 60a is positioned below the main surface 60b in the vertical direction.

### Step (e)

Step (e) is a step of polishing the interposer 60 so that the sealing material 8 disposed in the groove portion 61 is exposed. In step (e), the interposer 60 is polished from the main surface 60b toward the main surface 60a, whereby the interposer 60 is thinned. When the interposer 60 is polished until the sealing material 8 disposed in the groove portion 61 is exposed, the first portion 66 of the interposer 60 is removed and the plurality of second portions 67 remain as illustrated in FIG. 16B. When viewed from the thickness direction of the interposer 60, only the sealing material 8 is present between the adjacent second portions 67.

Next, as illustrated in FIG. 16C the bumps 7 are disposed on the interposer 60. In the present embodiment, the bumps 7 are disposed on the surface of each second portion 67 on a side opposite to the re-distribution layer 50. The bumps 7 are electrically connected to the wiring of the interposer 60.

### Step (f)

Step (f) is a step of individualizing the structure 200 for each of the plurality of regions 65 by cutting off the sealing material 8 along the groove portion 61 to acquire the plurality of semiconductor devices 201. As illustrated in FIG. 16C, in step (f), the sealing material 8 is cut off in the thickness direction of the interposer 60. Specifically, a portion of the sealing material 8 disposed in the groove portion 61 (a portion disposed between the plurality of second portions 67), a portion of the sealing material 8 disposed in the opening 52 of the re-distribution layer 50, and a portion of the sealing material 8 disposed between the plurality of semiconductor elements 202 are cut off together. As a result, the structure 200 is individualized for each of the plurality of regions 65. As described above, when viewed from the thickness direction of the interposer 60, only the sealing material 8 exists between the adjacent second portions 67. Therefore, when the sealing material 8 is cut off in step (f), the interposer 60 is not cut off. Note that, as in the first embodiment, the sealing material 8 is cut off using, for example, a dicing blade rotating at a high speed. As a result, the structure 200 is individualized, and a plurality of semiconductor devices 201 (see FIG. 13) are acquired. The individualized interposer 60 corresponds to the interposer 6 of the semiconductor device 201, and the individualized re-distribution layer 50 corresponds to the re-distribution layer 5 of the semiconductor device 201. Thus, the producing process of the semiconductor device 201 illustrated in FIG. 13 is completed.

As described above, according to the method for producing the semiconductor device 201 of the second embodiment, as in the first embodiment, it is possible to individualize the structure 200 by cutting off the sealing material 8 disposed in the groove portion 61 without cutting off the interposer 60. Therefore, when the structure 200 is individualized, for example, it is not necessary to use a blade for cutting off the interposer 60 in addition to the blade for cutting off the sealing material 8. As a result, for example, it is not necessary to replace the blade, and the production efficiency of the semiconductor device 201 can be improved. Other effects similar to those of the first embodiment can be obtained.

Although the embodiments of the present disclosure have been described in detail above, the present disclosure is not limited to the above embodiments.

The insulating portion 51 of the re-distribution layer 50 may be formed of an inorganic material. The inorganic material forming the insulating portion 51 may be silicon dioxide (SiO₂), silicon nitride (SiN), or silicon oxynitride (SiON). In a case where the insulating portion 51 is formed of an inorganic material, when the overlapping portion with the portion 61A in the re-distribution layer 50 is removed in step (a) (see FIG. 3), the re-distribution layer 50 may be diced by a blade to remove the overlapping portion. The removal of the overlapping portion in the re-distribution layer 50 and the formation of the groove portion 61 (see FIG. 4) may be performed together using the same blade.

In the producing process of the semiconductor devices 1 and 201, step (b) may be omitted. That is, the underfill 4 may not be disposed between the plurality of semiconductor elements 2 and 202 and the main surface 60a.

In the producing process of the semiconductor devices 1 and 201, step (d) may be omitted. That is, the sealing material 8 may not be polished and thinned so that the upper surface 2a of each of the semiconductor elements 2 and 202 is exposed from the sealing material 8. Specifically, the sealing material 8 may not be polished at all, or may be polished to such an extent that the upper surface 2a of each of the semiconductor elements 2 and 202 is not exposed from the sealing material 8.

The depth A1 of the groove portion 61 formed in the interposer 60 is not limited. The depth A1 may be less than 10% relative to the thickness T1 of the interposer 60 or greater than 60% relative to the thickness T1. The depth A1 may be smaller than 70 μm or larger than 470 μm.

The orientations of the semiconductor devices 1 and 201 when the semiconductor devices 1 and 201 are mounted on another electronic component are not limited. That is, the semiconductor devices 1 and 201 may be mounted such that the upper surfaces 2a of the semiconductor elements 2 and 202 are positioned above the lower surface 2b in the vertical direction, or the semiconductor device 1 may be mounted such that the upper surface 2a is positioned below the lower surface 2b in the vertical direction.

### REFERENCE SIGNS LIST

1,201 semiconductor device
2, 202, 202a, 202b semiconductor element
2a upper surface
2c side surface
4 underfill
5,50 re-distribution layer
6,60 interposer
8 sealing material
60a main surface (first main surface)
60b main surface (second main surface)
61 groove portion
61A portion (portion to be formed)
62 first groove
63 second groove
65 region
100,200 structure

1. A method for producing a semiconductor device, the method comprising:
preparing a structure including an interposer including a first main surface and a second main surface opposed to the first main surface, the interposer including a groove portion formed to divide the first main surface into a plurality of regions, and a plurality of semiconductor elements, at least one of the semiconductor elements being arranged on each of the regions;
sealing at least a part of each of the plurality of semiconductor elements with a sealing material such that the sealing material is disposed at least in the groove portion;
polishing the interposer from the second main surface toward the first main surface such that the sealing material disposed in the groove portion is exposed; and
individualizing the structure for each of the plurality of regions by cutting off the sealing material along the groove portion and acquiring a plurality of semiconductor devices.

2. The method for producing a semiconductor device according to claim 1, wherein the preparing the structure includes forming the groove portion having a depth of 10% to 60% with respect to a thickness of the interposer before being polished.

3. The method for producing a semiconductor device according to claim 1, wherein the preparing the structure includes forming the groove portion having a depth of 70 82 m to 470 μm.

4. The method for producing the semiconductor device according to claim 1, wherein the interposer is formed of silicon.

5. The method for producing a semiconductor device according to claim 1, wherein the preparing the structure includes:
forming a re-distribution layer on the first main surface before the groove portion is formed;
removing an overlapping portion of the re-distribution layer with a portion where the groove portion is to be formed; and
forming the groove portion in the interposer.

6. The method for producing a semiconductor device according to claim 5,
wherein a material forming the re-distribution layer includes a material having photosensitivity, and
wherein in the removing the overlapping portion, the overlapping portion is removed by performing exposure and development on the re-distribution layer.

7. The method for producing a semiconductor device according to claim 1, further comprising:
disposing an underfill between the plurality of semiconductor elements and the first main surface before the sealing.

8. The method for producing a semiconductor device according to claim 1,
wherein in the sealing, the sealing material is disposed so as to cover a side surface and an upper surface of each of the semiconductor elements, and
wherein the method further comprises polishing the sealing material such that the upper surface of each of the semiconductor elements is exposed from the sealing material.

9. The method for producing the semiconductor device according to claim 1, wherein the preparing the structure includes forming the groove portion by dicing the interposer using a first blade.

10. The method for producing a semiconductor device according to claim 9, wherein in the acquiring the plurality of semiconductor devices, the sealing material is cut off along the groove portion using a second blade.

11. The method for producing a semiconductor device according to claim 10, wherein a grain size of an abrasive grain of the first blade is larger than a grain size of an abrasive grain of the second blade.

12. The method for producing a semiconductor device according to claim 11,
wherein the grain size of the abrasive grain of the first blade is #2000 to #4000, and
wherein the grain size of the abrasive grain of the second blade is #320 to #600.

13. A structure comprising:
an interposer including a first main surface and a second main surface opposed to the first main surface; and
a plurality of semiconductor elements disposed on the first main surface, wherein the interposer includes a groove portion configured to divide the first main surface into a plurality of regions, and
wherein at least one of the plurality of semiconductor elements is disposed on each of the regions.

14. The structure according to claim 13, wherein the groove portion has a depth of 10% to 60% of a thickness of the interposer.

15. The structure according to claim 13, wherein the groove portion has a depth of 70 μm to 470 μm.

16. The structure according to claim 13,
wherein the groove portion is formed in a lattice shape including a plurality of first grooves along a first direction and a plurality of second grooves along a second direction intersecting the first direction,
wherein an interval between the first grooves adjacent to each other is 10 mm to 100 mm, and
wherein an interval between the second grooves adjacent to each other is 20 mm to 100 mm.

17. A semiconductor device comprising:
an interposer;
at least one semiconductor element disposed on a main surface of the interposer; and
a sealing material configured to seal the interposer and the at least one semiconductor element,
wherein the sealing material covers at least a side surface of the interposer.

18. The semiconductor device according to claim 17, further comprising:
a re-distribution layer configured to connect the interposer and the at least one semiconductor element,
wherein the sealing material further covers a side surface of the re-distribution layer.
